(19) United States
(12) Patent Application Publication
(10) Pub. No.: US 2022/0083835 A1
(43) Pub. Date: Mar. 17, 2022

(54) DATA COMPRESSION DEVICE AND METHOD FOR A DEEP NEURAL NETWORK

(71) Applicant: Cvitek Co. Ltd., Beijing (CN)

(72) Inventors: Shu-Wei TENG, Taichung City (TW); Chin-Chung YEN, New Taipei City (TW)

(21) Appl. No.: 17/470,997

(22) Filed: Sep. 9, 2021

(30) Foreign Application Priority Data
Sep. 16, 2020 (CN) 202010976210.X

(51) Int. Cl. G06N 3/04

(52) U.S. Cl. CPC G06N 3/04

(57) ABSTRACT

A data compression method for a deep neural network is provided. The data compression method includes following steps. Pleural items of original data are re-mapped according to at least one offset value and a sign value to obtain pleural items of mapped data. A distribution center of the mapped data is aligned with 0 and all of the mapped data are non-negative integers. Pleural data blocks of the mapped data are encoded using at least two encoding modes to generate an encoding data.

This application claims the benefit of People's Republic of China application Serial No. 202010976210.X, filed Sep. 16, 2020, the subject matter of which is incorporated herein by reference.

### BACKGROUND OF THE INVENTION

### Field of the Invention

The invention relates in general to a data compression device and method, and more particularly to a data compression device and method for a deep neural network.

### Description of the Related Art

Deep neural network (DNN) can be used in several fields, such as image recognition and voice recognition, to resolve various problems. A deep neural network needs to work with high performance hardware accelerator and relevant hardware to achieve a desired efficacy.

The scale of a deep neural network affects its hardware cost. For example, the usage of memory and the consumption of bandwidth increases as the scale of the deep neural network grows. Therefore, it has become a prominent task for the industry to compress the data of a deep neural network to reduce the usage of memory and the consumption of bandwidth.

### SUMMARY OF THE INVENTION

The invention is directed to a data compression device and method for a deep neural network. The data compression device and method of the invention effectively compress the weight data and activation data in an integer format or a floating-point format of a deep neural network to reduce the usage of memory and the consumption of bandwidth.

According to one embodiment of the present invention, a data compression device for a deep neural network is provided. The data compression device includes a data mapping unit and a data encoding unit. The data mapping unit is used to re-map pleural items of original data according to at least one offset value and a sign value to obtain pleural items of mapped data. A distribution center of the mapped data is aligned with 0 and all of the mapped data are non-negative integers. The data encoding unit is used to encode pleural data blocks of the mapped data using at least two encoding modes to generate an encoding data.

According to another embodiment of the present invention, a data compression method for a deep neural network is provided. The data compression method includes following steps. Pleural items of original data are re-mapped according to at least one offset value and a sign value to obtain pleural items of mapped data. A distribution center of the mapped data is aligned with 0 and all of the mapped data are non-negative integers. Pleural data blocks of the mapped data are encoded using at least two encoding modes to generate an encoding data.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic diagram of a data compression device for a deep neural network according to an embodiment of the present invention.

FIG. 2 is a flowchart of a data compression method for a deep neural network according to an embodiment of the present invention.

FIG. 3 is a distribution diagram of pleural items of original data according to an embodiment of the present invention.

FIG. 4 is a flowchart of sub-steps of step S110 according to an embodiment of the present invention.

FIG. 5 is a distribution diagram of pleural items of original data with a distribution center being aligned with 0 according to an embodiment of the present invention.

FIG. 6 is a flowchart of step S120 according to an embodiment of the present invention.

FIG. 7 is a schematic diagram of an encoding data when the original data is in an INT8 format according to an embodiment of the present invention.

FIG. 8 is a schematic diagram of an encoding data when the original data is the exponent part in a BF16 format according to another embodiment of the present invention.

FIG. 9 is a schematic diagram of a data decompression device for a deep neural network according to an embodiment of the present invention.

FIG. 10 is a flowchart of a data decompression method for a deep neural network according to an embodiment of the present invention.

FIG. 11 is a schematic diagram of an application scenario of a data compression device for a deep neural network according to an embodiment of the present invention.

FIG. 12 is a schematic diagram of an application scenario of a data compression device for a deep neural network according to another embodiment of the present invention.

### DETAILED DESCRIPTION OF THE INVENTION

For the object, technical features and effects of the present invention to be more easily understood by anyone ordinary skilled in the technology field, a number of exemplary embodiments are disclosed below with detailed descriptions and accompanying drawings.

Although the present disclosure does not illustrate all possible embodiments, other embodiments not disclosed in the present disclosure are still applicable. Moreover, the dimension scales used in the accompanying drawings are not based on actual proportion of the product. Therefore, the specification and drawings are for explaining and describing the embodiment only, not for limiting the scope of protection of the present disclosure. Furthermore, descriptions of the embodiments, such as detailed structures, manufacturing procedures and materials, are for exemplification purpose only, not for limiting the scope of protection of the present disclosure. Suitable modifications or changes can be made to the structures and procedures of the embodiments to meet actual needs without breaching the spirit of the present disclosure.

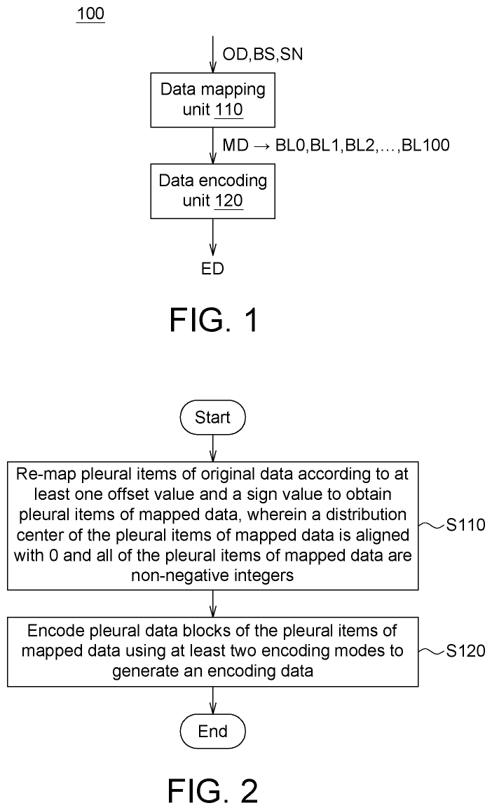

Referring to FIG. 1, a schematic diagram of a data compression device 100 for a deep neural network according to an embodiment of the present invention is shown. The data compression device 100 includes a data mapping unit 110 and a data encoding unit 120. The data mapping unit 110 and the data encoding unit 120 can be a chip, a circuit board or a circuit. The weights or activation values of a deep neural network can be in an integer format or a floating-point format. For example, the weights and activation values are in an 8-bit signed integer (INT8) format, an 8-bit unsigned integer (UINT8) format, a 16-bit brain floating-point (BF16) format or a 16-bit floating-point (FP16) format, and the present invention is not limited thereto. Suppose the original data OD is in the INT8 format or the exponent part in the BF16 format. The sign bit and fraction in the BF16 format can be directly encoded by the data encoding unit 120 using a fixed-length coding. It should be noted that in a deep neural network, the exponent part of each of the weights or activation values in the floating-point format has a concentration property, and the data size can be effectively compressed by performing the data compression method of the present invention on the exponent part.

Refer to both FIG. 1 and FIG. 2. FIG. 2 is a flowchart of a data compression method for a deep neural network according to an embodiment of the present invention.

In step S110, pleural items of original data OD are re-mapped by the data mapping unit 110 according to at least one offset value BS and a sign value SN to obtain pleural items of mapped data MD, wherein a distribution center of the mapped data MD is aligned with 0 and all of the pleural items of mapped data MD are non-negative integers.

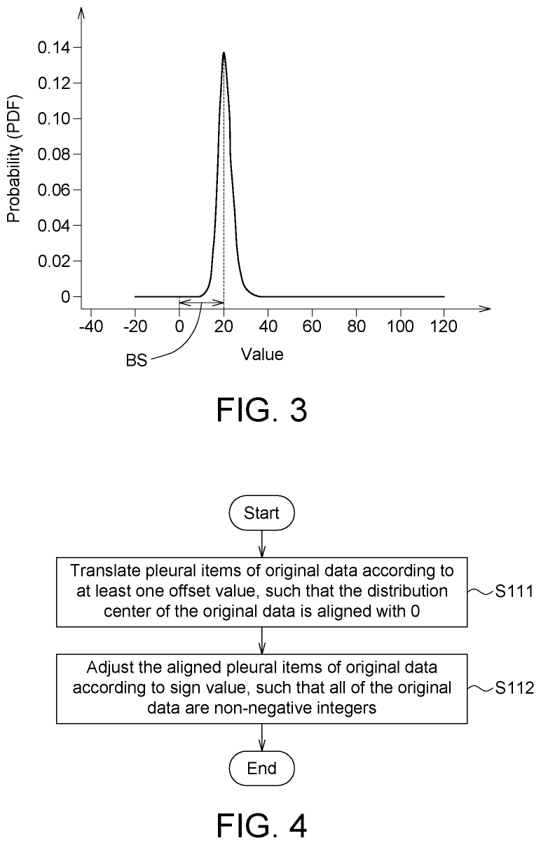

The offset value BS is an offset between a distribution center of pleural items of original data OD and 0. Referring to FIG. 3, a distribution diagram of pleural items of original data OD according to an embodiment of the present invention is shown. As indicated in FIG. 3, the distribution center of pleural items of original data OD has a value of 20, and the offset between the distribution center and 0 is 20, therefore the offset value BS is 20. The sign value SN is used to indicate whether any negative value exists after the distribution center of the original data OD is aligned with 0. For example, the sign value SN is set to indicate that negative value exists after the original data OD is aligned with 0; the sign value SN is not set to indicate that negative value does not exist after the original data OD is aligned with 0. In the present embodiment, a processing unit (not illustrated) analyzes the original data OD to obtain the offset value BS and the sign value SN. In an embodiment, the data mapping unit 110 aligns the distribution center of the original data OD with 0 according to two offset values BS, but the present invention is not limited thereto.

In step S120, pleural data blocks BL0, BL1, BL2, . . . , and BL100 of the mapped data MD are encoded by the data encoding unit 120 using at least two encoding modes to generate an encoding data ED. In an embodiment, each of the data blocks BL0, BL1, BL2, . . . , and BL100 is composed of 16 items of mapped data MD, but the present invention is not limited thereto. The encoding data ED includes a header column bit, an encoding mode column bit and the encoded data blocks BL0, BL1, BL2, and BL100. The header column bit is used to record the offset value BS and the sign value SN, the encoding mode column bit is used to record the encoding mode used in each of the data blocks BL0, BL1, BL2, . . . , and BL100.

Details of step S110 and S120 are disclosed below.

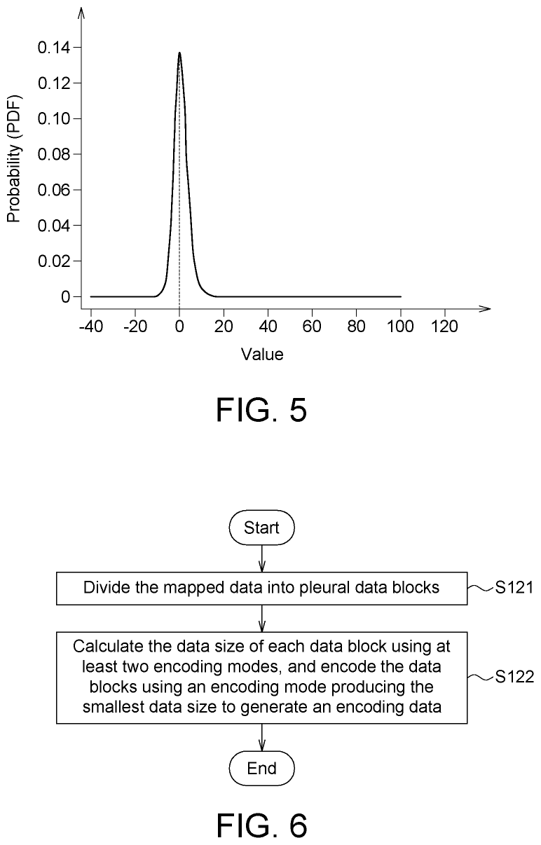

Refer to FIG. 4 and FIG. 5. FIG. 4 is a flowchart of sub-steps of step S110 according to an embodiment of the present invention. FIG. 5 is a distribution diagram of pleural items of original data OD with a distribution center being aligned with 0 according to an embodiment of the present invention. Step S110 includes sub-steps S111 and S112.

In sub-step S111, pleural items of original data OD are translated by the data mapping unit 110 according to at least one offset value BS, such that the distribution center of the original data OD is aligned with 0. Let the pleural items of original data OD of FIG. 3 be taken for example. The data mapping unit 110 deducts the value of each of original data OD by the offset value BS (that is, 20), such that the distribution center of the original data OD is aligned with 0 as indicated in FIG. 5.

Next, in sub-step S112, the aligned pleural items of original data OD are adjusted by the data mapping unit 110 according to sign value SN, such that all of the original data OD are non-negative integers. Furthermore, when the sign value SN is set, the data mapping unit 110 adjusts the aligned original data OD to be non-negative integers according to a conversion formula. In an embodiment, the conversion formula can be y=|x|×2−sign y=|x|×2−sign, wherein y is the value of the aligned original data OD after conversion, and x is the value of the aligned original data OD. Sign is the positive sign or negative sign of the value of the aligned original data OD, wherein the positive sign is 0, and the negative sign is 1.

After step S111 and S112 are performed, pleural items of mapped data MD are obtained, wherein the distribution center of the mapped data MD is aligned with 0 and all of the mapped data MD are non-negative integers.

Referring to FIG. 6, a flowchart of step S120 according to an embodiment of the present invention is shown. The step S120 includes sub-steps S121 and S122.

In sub-step S121, the mapped data MD are divided into pleural data blocks BL0, BL1, BL2, . . . , and BL100 by the data encoding unit 120.

In sub-step S122, the data size of each of the data blocks BL0, BL1, BL2, . . . , and BL100 encoded by the data encoding unit 120 using at least two encoding modes is calculated, and the data blocks are encoded using an encoding mode producing the smallest data size to generate an encoding data ED. In the present embodiment, the at least two encoding modes are selected from the first order (k=1) and second order (k=2) Golomb-Rice coding and the n-bit fixed-length coding, but the present invention is not limited thereto. In another embodiment, the at least two encoding modes are selected from the first order (k=1), second order (k=2) and fourth order (k=4) Golomb-Rice coding and the n-bit fixed-length coding. That is, each of the data blocks BL0, BL1, BL2, . . . , and BL100 is encoded using the encoding mode producing the smallest data size to generate an encoding data ED.

Refer to Table 1. Table 1 shows the fixed-length coding and the first order (k=1), second order (k=2) and fourth order (k=4) Golomb-Rice coding.

TABLE 1

| | | First order | Second | Fourth |
|---|---|---|---|---|
| | | (k = 1) | order | order |
| | Fixed | Golomb- | (k = 2) | (k = 4) |
| | length | Rice | Golomb- | Golomb- |
| Value | coding | coding | Rice coding | Rice coding |
| 0 | 00000000 | 10 | 100 | 10000 |
| 1 | 00000001 | 11 | 101 | 10001 |
| 2 | 00000010 | 010 | 110 | 10010 |
| 3 | 00000011 | 011 | 111 | 10011 |
| 4 | 00000100 | 0010 | 0100 | 10100 |
| 5 | 00000101 | 0011 | 0101 | 10101 |
| 6 | 00000110 | 00010 | 0110 | 10110 |
| 7 | 00000111 | 00011 | 0111 | 10111 |
| 8 | 00001000 | 000010 | 00100 | 11000 |
| 9 | 00001001 | 000011 | 00101 | 11001 |
| 10 | 00001010 | 0000010 | 00110 | 11010 |
| 11 | 00001011 | 0000011 | 00111 | 11011 |
| 12 | 00001100 | 00000010 | 000100 | 11100 |
| 13 | 00001101 | 00000011 | 000101 | 11101 |
| 14 | 00001110 | 000000010 | 000110 | 11110 |
| 15 | 00001111 | 000000011 | 000111 | 11111 |

In the present invention, data concentrated in dense distribution is encoded via the encoding mode with shorter encoding length to achieve compressed data size reduction.

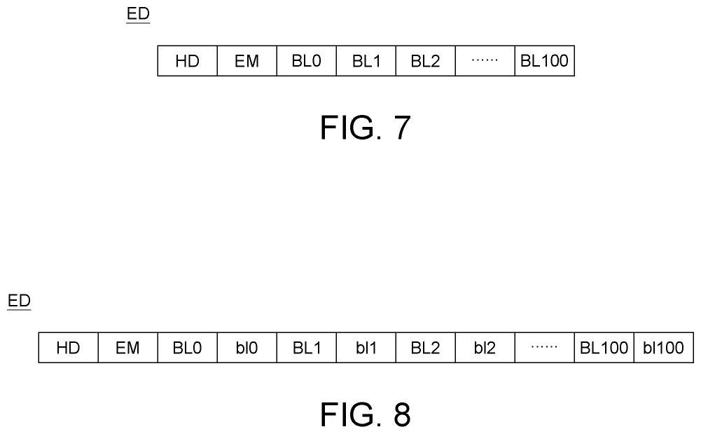

Referring to FIG. 7, a schematic diagram of an encoding data when the original data OD is in an INT8 format according to an embodiment of the present invention is shown. The encoding data ED includes a header column HD, an encoding mode column bit EM and encoded data blocks BL0, BL1, BL2, . . . , and BL100. The header column HD is used to record the offset value BS and the sign value SN. The encoding mode column bit EM is used to record the encoding mode used in each of the data blocks BL0, BL1, BL2, . . . , and BL100.

Referring to FIG. 8, a schematic diagram of an encoding data ED when the original data OD is the exponent part of the BF16 format according to another embodiment of the present invention is shown. The encoding data ED includes a header column HD, an encoding mode column bit EM, encoded data blocks BL0, BL1, BL2, . . . , and BL100 and encoded data blocks bl0, bl1, bl2, . . . , bl100. The header column HD is used to record the offset value BS and the sign value SN. The encoding mode column bit EM is used to record the encoding mode used in each of the data blocks BL0, BL1, BL2, . . . , and BL100. The encoded data blocks bl0, bl1, bl2, . . . , bl100 are sign bit and fraction part of BF16. The encoded data blocks bl0, bl1, bl2, . . . , bl100 are generated using the fixed-length coding. In an embodiment, if the exponent part is 0, the corresponding sign bit and fraction are not encoded.

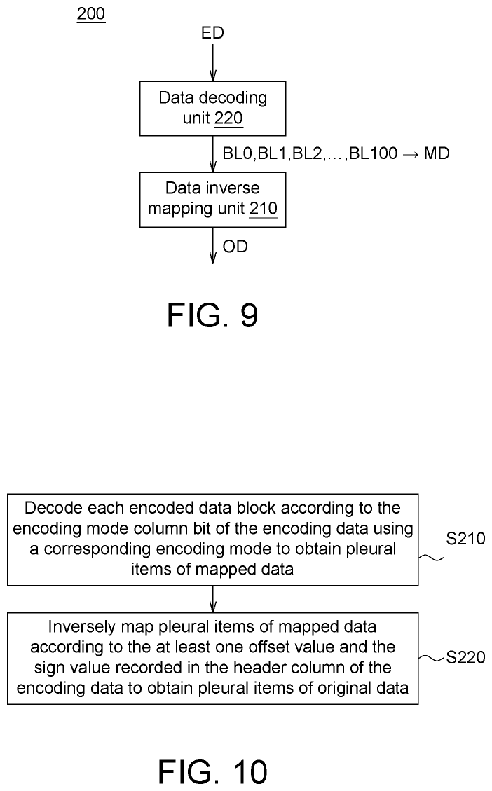

Referring to FIG. 9, a schematic diagram of a data decompression device 200 for a deep neural network according to an embodiment of the present invention is shown. The data decompression device 200 includes a data inverse mapping unit 210 and a data decoding unit 220. The data inverse mapping unit 210 and the data decoding unit 220 can be a chip, a circuit board or a circuit.

Referring to both FIG. 9 and FIG. 10. FIG. 10 is a flowchart of a data decompression method for a deep neural network according to an embodiment of the present invention.

In step S210, each of encoded data blocks BL0, BL1, BL2, . . . , and BL100 is decoded by the data decoding unit 220 according to the encoding mode column bit EM of the encoding data ED using a corresponding encoding mode to obtain pleural items of mapped data MD. The mapped data MD are composed of data blocks BL0, BL1, BL2, . . . , and BL100. Furthermore, when the encoding data ED includes the encoded data blocks generated using the fixed-length coding, the data decoding unit 220 decodes these data blocks using a corresponding decoding method.

In step S220, pleural items of mapped data MD are inversely mapped by the data inverse mapping unit 210 according to the at least one offset value BS and the sign value SN recorded in the header column HD of the encoding data ED to obtain pleural items of original data OD. To put it in greater details, the data inverse mapping unit 210 adjusts the mapped data MD according to sign value SN. When sign value SN is set, the data inverse mapping unit 210 adjusts the mapped data MD according to a inverse conversion formula. The inverse conversion formula corresponds to the said conversion formula. Then, the mapped data MD is translated by the data inverse mapping unit 210 according to the offset value BS to obtain pleural items of original data OD.

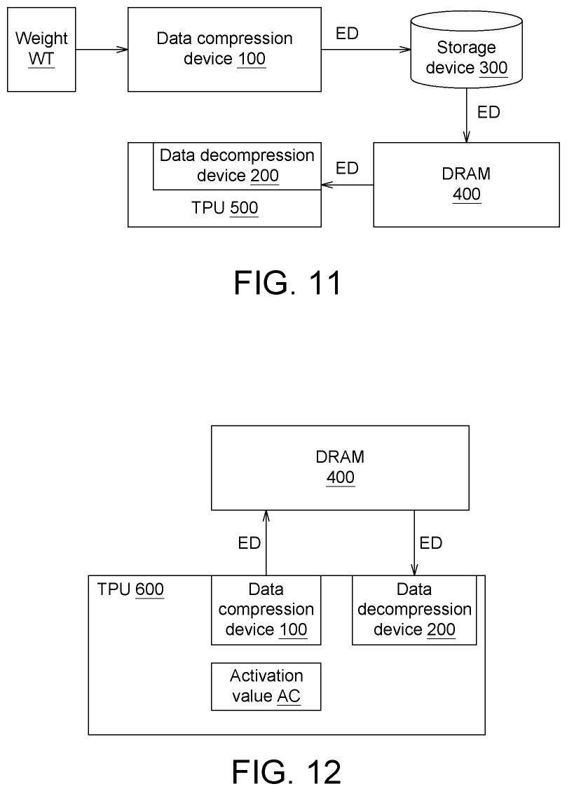

Referring to FIG. 11, a schematic diagram of an application scenario of a data compression device 100 for a deep neural network according to an embodiment of the present invention is shown. The weight WT of the deep learning model is inputted to the data compression device 100, and the data compression device 100 performs a data compression method on the weight WT to obtain an encoding data ED. The encoding data ED can be stored in a storage device 300, such as a flash memory. When the tensor processing unit (TPU) 500 performs a deep learning model, the encoding data ED is firstly loaded to a random access memory (DRAM) 400, and the data decompression device 200 of the tensor processing unit 500 performs a data decompression method on the encoding data ED to obtain the weight WT of the deep learning model.

Referring to FIG. 12, a schematic diagram of an application scenario of a data compression device 100 for a deep neural network according to another embodiment of the present invention is shown. When tensor processing unit 600 performs a deep learning model, the tensor processing unit 600 needs to load/store an activation value AC from the random access memory 400. The data compression device 100 of the tensor processing unit 600 performs a data compression method on the activation value AC to obtain an encoding data ED and further stores the encoding data ED to the random access memory 400. The tensor processing unit 600 reads the encoding data ED from the random access memory 400, and the data decompression device 200 performs a data decompression method on the encoding data ED to obtain an activation value AC.

The data compression device and method for a deep neural network disclosed in the present invention can effectively compress the the weight data and activation data in an integer format or exponent part of a floating-point format to reduce the usage of memory and the consumption of bandwidth.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A data compression device for a deep neural network, comprising:
a data mapping unit used to re-map pleural items of original data according to at least one offset value and a sign value to obtain pleural items of mapped data, wherein a distribution center of the pleural items of mapped data is aligned with 0 and all of the pleural items of mapped data are non-negative integers;
a data encoding unit used to encode pleural data blocks of the pleural items of mapped data using at least two encoding modes to generate an encoding data.

2. The data compression device according to claim 1, wherein the pleural items of original data are pleural weights of the deep neural network.

3. The data compression device according to claim 1, wherein the pleural items of original data are pleural activation values of the deep neural network.

4. The data compression device according to claim 1, wherein each of the pleural items of original data is in an integer format.

5. The data compression device according to claim 1, wherein each of the pleural items of original data is in a 16-bit brain floating-point (BF16) format or a 16-bit floating-point (FP16) format.

6. The data compression device according to claim 5, wherein the data mapping unit is further used to re-map exponent parts of the pleural items of original data in the BF16 format according to the at least one offset value and the sign value.

7. The data compression device according to claim 6, wherein when one of the exponent parts is 0, the data encoding unit does not encode corresponding sign bit and fraction.

8. The data compression device according to claim 1, wherein the at least two encoding modes are at least two encoding modes of Golomb-Rice coding or n-bit fixed-length coding.

9. The data compression device according to claim 1, wherein the encoding data comprises a header column bit, an encoding mode column bit and the pleural data blocks which are encoded; the header column bit records the at least one offset value and the sign value, and the encoding mode column bit records one of the encoding mode used in each of the pleural data blocks.

10. A data compression method for a deep neural network, comprising:
re-mapping pleural items of original data according to at least one offset value and a sign value to obtain pleural items of mapped data, wherein a distribution center of the pleural items of mapped data is aligned with 0 and all of the pleural items of mapped data are non-negative integers; and
encoding pleural data blocks of the pleural items of mapped data using at least two encoding modes to generate an encoding data.

11. The data encoding method according to claim 10, wherein the pleural items of original data are pleural weights of the deep neural network.

12. The data encoding method according to claim 10, wherein the pleural items of original data are pleural activation values of the deep neural network.

13. The data encoding method according to claim 10, wherein each of the pleural items of original data is in an integer format.

14. The data encoding method according to claim 10, wherein each of the pleural items of original data is in a BF16 format or an FP16 format.

15. The data encoding method according to claim 14, wherein the step of re-mapping the pleural items of original data according to the at least one offset value and the sign value comprises:
re-mapping exponent parts of the pleural items of original data in the BF16 format according to the at least one offset value and the sign value.

16. The data encoding method according to claim 15, wherein when one of the exponent parts is 0, corresponding sign bit and fraction are not encoded.

17. The data encoding method according to claim 10, wherein the at least two encoding modes are at least two encoding modes of Golomb-Rice coding or n-bit fixed-length coding.

18. The data encoding method according to claim 10, wherein the encoding data comprises a header column bit, an encoding mode column bit and the pleural data blocks which are encoded; the header column bit records the at least one offset value and the sign value and the encoding mode column bit records one of the encoding mode used in each of the pleural data blocks.
